(19) United States
(12) Patent Application Publication
(10) Pub. No.: US 2025/0028884 A1
(43) Pub. Date: Jan. 23, 2025

(54) INFORMATION PROCESSING DEVICE, INFORMATION PROCESSING METHOD, AND NON-TRANSITORY COMPUTER READABLE MEDIUM

(71) Applicants: Preferred Networks, Inc., Tokyo-to (JP); ENEOS Corporation, Tokyo (JP)

(72) Inventor: Akihide HAYASHI, Tokyo-to (JP)

(73) Assignees: Preferred Networks, Inc., Tokyo-to (JP); ENEOS Corporation, Tokyo (JP)

(21) Appl. No.: 18/775,349

(22) Filed: Jul. 17, 2024

(30) Foreign Application Priority Data
Jul. 20, 2023 (JP) 2023-118608

(51) Int. Cl. G06F 30/27

(52) U.S. Cl. CPC G06F 30/27

(57) ABSTRACT

An information processing device includes one or more memories and one or more processors. The one or more processors are configured to: set a first structure of a plurality of atoms; and repeatedly calculate a structural change of the plurality of atoms from the first structure to a second structure of the plurality of atoms under a condition to be satisfied by at least the second structure with regard to an atomic structure to focus on, the condition including an inequality, to search for a trajectory of a structure of the plurality of atoms from the first structure to the second structure.

### CROSS REFERENCE TO THE RELATED APPLICATIONS

This application is based upon and claims the benefit of priority from the Japanese Patent Application No. 2023-118608, filed on Jul. 20, 2023, the entire contents of which are incorporated herein by reference.

### FIELD

This disclosure relates to an information processing device, an information processing method, and a non-transitory computer readable medium.

### BACKGROUND

Ease of a chemical reaction can be calculated from an initial state before reaction and a final state after reaction and an energy difference (activation energy) in a transition state existing between the initial state and the final state. Examples of the method of finding the energy in the transition state include the NEB (Nudged Elastic Band) method in which a user gives a combination of the initial state and the final state and ADDF (Anharmonic Downward Distortion Following) in which the user does not need to explicitly give the combination of the initial state and the final state.

Further, there is a method such as AFIR (Artificial Force Induced Reaction) of applying pseudo attractive force and repulsive force between specific molecules and between specific atoms to make a specific reaction more likely to occur so as to automatically search for a reaction process between a plurality of reactants.

### BRIEF DESCRIPTION OF DRAWINGS

FIG. 1 is a flowchart illustrating an example of processing of an information processing device according to an embodiment.

FIG. 2 is a block diagram illustrating an example of implementation of an information processing device according to an embodiment.

### DETAILED DESCRIPTION

According to one embodiment, an information processing device includes one or more memories and one or more processors. The one or more processors are configured to: set a first structure of a plurality of atoms; and repeatedly calculate a structural change of the plurality of atoms from the first structure to a second structure of the plurality of atoms under a condition to be satisfied by at least the second structure with regard to an atomic structure to focus on, the condition including an inequality, to search for a trajectory of a structure of the plurality of atoms from the first structure to the second structure.

A problem to be solved by the embodiments of this disclosure is not limited to the above-described problem and can be a problem corresponding to the effects mentioned in the embodiments as examples of non-limiting problems. In other words, the problem corresponding to at least arbitrary one of the effects described in the explanation of the embodiments of this disclosure can be the problem to be solved in this disclosure.

Hereinafter, embodiments of the present invention will be explained with reference to the drawings. The drawings and the explanation of the embodiments are indicated as examples and are not intended to limit the present invention.

In this disclosure, a chemical reaction path of a system including a plurality of atoms such as a molecule is searched for by an information processing device. The information processing device sets, by a form including at least one or more inequalities, a condition of constraint (sometimes called a constraint condition in this disclosure) regarding an index of a positional relationship of at least one or more atoms (atomic structure to focus on) among the plurality of atoms (as an example, a coordinate in a predetermined direction of one atom (for example, a z-coordinate of an atom relative to a fixed slab spreading in xy directions of a space, a bond distance, a bond angle, and a dihedral angle between/among atoms), and calculates a change in the structure of the system including a plurality of atoms under this condition. The information processing device may continuously change the structure of the system until the set condition of the inequality is satisfied. The information processing device repeatedly performs the calculation of a structural change while updating the force to be applied on at least one atom among the plurality of atoms under this condition to search for (acquire) a trajectory of the final chemical reaction path. The information processing device may repeatedly calculate and update the force changing the structure of the system so as to satisfy the set condition of the inequality. In this disclosure, the molecular structure may be exemplified as a system including a plurality of atoms and a molecule and a molecular structure as its structure, and the molecular structure may be replaced with the system including a plurality of atoms and the structure of the system (structure of a plurality of atoms), respectively in the following explanation.

Hereinafter, the information processing device can execute steps by a processing circuit included in the information processing device or a processing circuit included in one or a plurality of other information processing devices.

First, variables and so on to be used in this disclosure will be explained.

A molecular coordinate is assumed to be x. This molecular coordinate represents the coordinates of atoms constituting a molecule. The molecular coordinate is expressed, for example, as a 3N-dimensional vector if the molecule includes N atoms.

A user coordinate is assumed to be C(x). This user coordinate is an index of a positional relationship between two or more atoms to focus on (atomic structure to focus on) in a chemical reaction in a molecule, and is defined by a scalar value. C(x) has, for example, the molecular coordinate x being the 3N-dimensional vector as an argument. In this disclosure, the search for the chemical reaction path is executed by repeatedly performing the calculation of the force to be applied on at least one atom and the calculation of a change in the atomic structure based on the calculated force, under the condition including an inequality for the user coordinate C(x) which can be expressed by a linear or non-linear function.

C(x) may be, for example, a function expressing an amount to be acquired from a position of an atom in a molecule. C(x) may be, for example, information including the coordinate in the predetermined direction (for example, the z-coordinate) of one atom. C(x) may be, for example, information including the bond distance between two atoms. Further, C(x) may be, for example, information including the bond angle formed by three or more atoms or the dihedral angle. Further, C(x) may be, for example, an amount which can be derived from the information such as the bond distance, the bond angle, or the dihedral angle.

Energy in the molecular structure having the molecular coordinate x is expressed by E(x). This energy E(x) is expressed by a function using the molecular coordinate x indicating the molecular structure as an argument to acquire the scalar value.

The force applied on a molecule is expressed by F(x). This force can be expressed by differentiation (position differentiation) of the energy E(x) of the molecular coordinate x.

$$F ( x ) = - ∇ E ( x ) \qquad ( 1 )$$

With the above variables and functions and the condition of the inequality for the user coordinate C(x), the information processing device relating to this disclosure realizes the search for the reaction path. The information processing device uses input information in the processing of changing the molecular structure (namely, a parameter set ScanP explained later as the information to be used for the processing) as an initial molecular structure (molecular coordinate x in the initial molecular structure), a definition of the user coordinate C(x) and its objective value Ce, and a parameter f defining the magnitude of the driving force. Note that the input information does not need to be limited to the above, and may have added information other than the above information.

The user coordinate C(x) and its objective value Ce can form an inequality expressing the constraint on the user coordinate, and the force to be applied on at least one atom included in a molecule can be calculated according to the condition expressed by this inequality. As in the following example, these C(x) and Ce can be arbitrarily set in appropriate ranges by the user.

Further, the user may define a plurality of C(x)s and a plurality of Ces as their objective values. In other words, the information processing device may set a plurality of conditions of the inequality formed by an ith user coordinate Cᵢ(x) and its objective value Cie. For example, the information processing device may set the plurality of conditions of the inequality by setting a bond distance C₁(x) between predetermined two atoms as a first C(x), setting a bond distance C₂(x) between other predetermined two atoms as a second C(x), setting a bond angle C₃(x) among predetermined three atoms as a third C(x), setting a dihedral angle C₄(x) among predetermined four atoms as a fourth C(x), and setting C₁e, C₂e, C₃e, C₄e as their respective objective values. In this event, the orientation of an inequality sign in each inequality may be decided according to a condition desired by the user. Hereinafter, C(x) and Ce indicate one or more Cᵢ(x)s and Cᵢes.

The information processing device acquires based on the above input, as an output of the chemical reaction path search, a final structure (molecular coordinate x in the final structure) changing from the initial molecular structure, satisfying a constraint Cᵢ(x)>=Cᵢe on the user coordinate, for example, for all i's, and satisfying an end condition of the structural change, and a trajectory connecting the initial molecular structure to the final structure (sequence of molecular coordinates x corresponding to the molecular structures at respective times in a process of changing the molecular structure from the initial molecular structure to the final structure, which may be read as a trajectory of the molecular structure). In this disclosure, the processing of calculating the structural change from a structure which is a start point to the final structure where the end condition is satisfied under one or more constraints expressed by the inequality regarding the molecular structure being a target and outputting the trajectory of the structural change is called a scan. Note that the processing in this disclosure can be used also for the processing of generating another molecular structure from the current molecular structure.

The information processing device may apply, for example, in parallel (simultaneously) or sequentially a plurality of conditions expressed by the inequality of the user coordinate Cᵢ(x) and its objective value Cᵢe as will be explained later in the scan processing, and may combine the parallel application and the sequential application of the conditions. The information processing device may perform the scan processing by changing the molecular structure while repeatedly calculating the force to be applied on at least one atom included in a molecule according to the condition to be applied.

### First Embodiment

Examples of the scan processing according to an embodiment include a method of solving a differential equation in which the force in the coordinate direction of the constraint on the user coordinate C(x) is changed. In this method, the trajectory is obtained by numerically solving a differential equation by using Fscan(x) obtained by changing the force F(x) applied on the molecule regarding a direction parallel to the position differentiation (V̅C(x)) of the user coordinate. This Fscan(x) corresponds to the force to be applied on at least one atom included in the molecule for changing the molecular structure.

The force vertical to the position differentiation of C(x) is expressed by eq. 2.

$${F}_{⊥} ( x ) = F ( x ) - {\sum }_{i} \frac{F ( x ) \cdot ∇ {C}_{i} ( x )}{∇ {C}_{i} ( x ) \cdot ∇ {C}_{i} ( x )} ∇ {C}_{i} ( x ) \qquad ( 2 )$$

The force Fscan(x) is defined, for example, as eq. 3 for a vertical force F⊥(x). Fscan(x) is a function to be case-divided by the condition of the inequality expressing the constraint on the user coordinate C(x), and the equation for calculating the force (value of force) is switched based on the condition of the inequality expressing the constraint on the user coordinate. In other words, Fscan(x) is a function whose shape is set based on the inequality.

Note that in the following eq. 3, such a constraint that each user coordinate Cᵢ(x) becomes its objective value Cᵢe or more is assumed, but the orientation of an inequality sign with respect to the objective value Cᵢe may be appropriately changed for each user coordinate Cᵢ(x) according to the type of the constraint on the user coordinate Cᵢ(x). This enables the calculation of the force Fscan(x) based on the appropriate constraint desired by the user and the trajectory based on the force Fscan(x).

$${F}_{scan} ( x ) = \{ \begin{matrix}{F}_{⊥} ( x ) + {\sum }_{i} {α}_{i} \frac{∇ {C}_{i} ( x )}{\vert ∇ {C}_{i} ( x ) \vert} , & C ( x ) < {C}_{e} \\ {F}_{⊥} ( x ) , & C ( x ) \geq {C}_{e}\end{matrix} \qquad ( 3 )$$

The information processing device may calculate Fscan(x) based on eq. 3. Note that in a region where the condition is branched, for example, a micro range including Cᵢ(x)=Cᵢe, Fscan(x) can be defined so that functions respectively indicating Cᵢ(x)<Cᵢe and Cᵢ(x)>Cᵢe smoothly connect with each other. Further, in the region where the condition is branched, the functions may be defined so as to be a weighted sum of the regions expressed in eq. 3.
α is a coefficient indicating how much F⊥ is displaced in a gradient direction of Cᵢ(x). As an example, the information processing device may decide αᵢ using a parameter fᵢ so as to satisfy the following condition expressed by eq. 4. The parameter fᵢ may be appropriately decided.

$$max norm ( {α}_{i} \frac{∇ {C}_{i} ( x )}{\vert ∇ {C}_{i} ( x ) \vert} ) = {f}_{i} \qquad ( 4 )$$

Note that maxnorm (·) is a function corresponding to taking a maximum value of a calculated norm of a vector corresponding to each atom in a molecule, and maxnorm (y) for an N atom (3N-dimensional vector y) can be described as follows by Python.

$$max norm ( y ) = max ( norm ( y \cdot reshape ( [ N , 3 ] ) , axis = 1 ) )$$

It can be grasped as a time change of the molecular coordinate x from the initial molecular structure to the final structure. Hence, the information processing device continues the calculation of Fscan by numerically solving an ordinary differential equation expressed by the following eq. 5 using an ODE solver (ordinary differential equation solver), until the force Fscan according to the molecular coordinate x becomes almost zero, for example, until the absolute value of Fscan falls below a predetermined value. By solving the ordinary differential equation, the molecular coordinate x at each time point can be obtained as a trajectory.

As explained above, by the scan processing of solving the ordinary differential equation based on the force Fscan(x) which is case-divided by the condition of the inequality expressing the constraint on the user coordinate C(x), the trajectory can be output. Note that the ordinary differential equation is not limited to the exemplified one, but may be an ordinary differential equation in which the force Fscan(x) is replaced with force F'scan(x) obtained by scaling the force Fscan(x) by a mass of each atom of the molecular structure or multiplying the force Fscan(x) by an arbitrary positive definite matrix or a preconditioning matrix.

$$\frac{dx}{dt} = {F}_{scan} ( x ) \qquad ( 5 )$$

### Second Embodiment

Though the scan processing is performed by numerically solving the differential equation while focusing on the force in the vertical direction of the gradient of the user coordinate in the above first embodiment, the displacement of the force is not limited to this method. In the information processing device according to an embodiment, an artificial force is added to the force F(X) applied on the molecule to constrain the lowest value (or highest value) of the user coordinate. An example of constraining the lowest value of the user coordinate will be explained below. As a non-limiting example of the artificial force, a log barrier can be used.

A barrier function is described as B(C(x)). B(C(x)) is desired to be a function which goes to infinity when C(x)=C0, becomes 0 when C(x)=C1, and monotonously decreases, but not limited to this. These C0, C1 satisfy, for example, the following inequality.

$${C}_{0} \leq C ( x ) \leq {C}_{1} \leq {C}_{e} \qquad ( 6 )$$

Among them, C1<=Ce does not need to be strictly satisfied, and may be slightly reversed. Further, as a non-limiting example, it is possible that C1=C0+ΔC and also that C1=min(Ce). As explained above, the barrier function B(C(x)) may be a function whose shape is set based on the inequality in Number (6).

The information processing device may perform the scan processing by executing optimization of the molecular structure based on a value Fscan(x) expressed by eq. 7 under constraint expressed by the inequality of eq. 6. The second term of eq. 7 corresponds to the artificial force to be added to the force F(x) applied on the molecule, and the optimization is the processing of finding the smallest value (minimum value) of the sum of energy E(x)+barrier function B(C(x)), based on the force Fscan(x) changing in value based on the condition of the inequality expressing the constraint on the user coordinate.

$${F}_{scan} ( x ) = F ( x ) - {\sum }_{i} ∇ {B}_{i} ( {C}_{i} ( x ) ) \qquad ( 7 )$$

If C(x)<Ce as a result of the optimization, C0 and C1 are reset and the optimization is continued. In this case, C(x)>=Ce may be regarded as a completion condition of the arithmetic calculation. For the resetting of C0 and C1, C0 may be set to a value smaller than C(x) at the optimization end time point and larger than C0 that is currently set, and C1 may be set to a value larger than C1 that is currently set. The trajectory may include not only the molecular structure at the optimization end time point but also the molecular structure changing during the optimization.

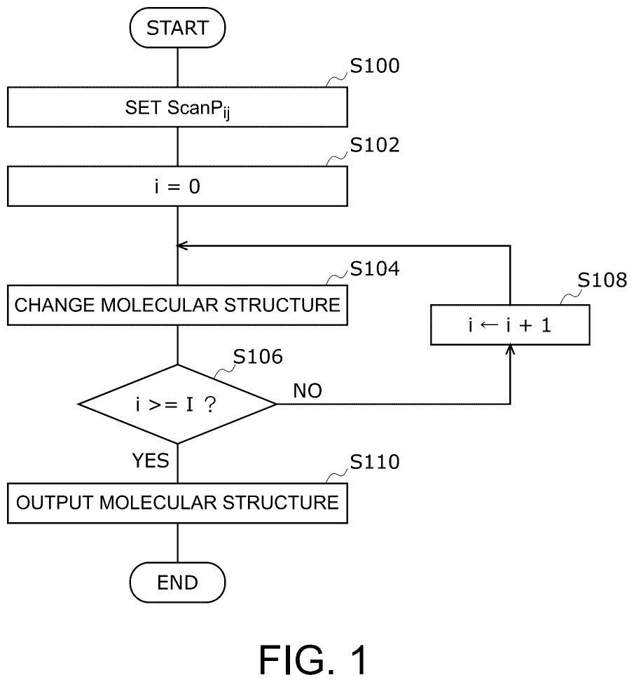

FIG. 1 is a flowchart illustrating a part of the flow of the above processing.

For the constraint on the user coordinate Cᵢ(x), a parameter set including the Cᵢ(x), a corresponding objective value Cᵢe, and a parameter fᵢ as ScanP. ScanP may include information representing the orientation of the inequality sign in the inequality using Cᵢ(x) and Cᵢe, and information indicating the way to update C(x), Ce, C0, C1.

In the scan, in the case of applying constraints on a plurality of user coordinates, the user defines the parameter set ScanP for each constraint. In other words, the information processing device accepts and sets a plurality of parameter sets ScanP. Here, when the user desires to apply in parallel and/or sequentially a plurality of constraints, the user may define the plurality of parameter sets ScanP in a double list structure as an example.

In this disclosure, the user defines the plurality of parameter sets ScanP in a form of List[List[ScanP]], and thereby may list one or more parameter sets ScanP desired to be applied in parallel as List[ScanP] by an inner List, and list one or more parameter sets ScanP (List[ScanP]) in the order desired to be applied sequentially as List[List[ScanP]] by an outer List.

The information processing device accepts the plurality of parameter sets List[List[ScanP]] as an input. The information processing device pops each parameter set ScanP one by one from List[ScanP] being a first list, and executes the scan processing in which all of the corresponding constraints are applied (namely, the scan processing in which all of the corresponding constraints are applied in parallel), on the initial molecular structure based on all of the popped ScanPs to thereby change the molecular structure from the initial molecular structure.

For the scan processing of calculating the change in the molecular structure, the methods explained in the first embodiment and the second embodiment can be employed.

Each parameter set ScanP is popped one by one from a List[ScanP] being the next list at the timing when the molecular structure has changed to the objective value Ce designated regarding all of the constraints, and the scan processing in which all of the corresponding constraints are applied is executed on the final structure of the scan processing based on the first list, based on all of the popped ScanPs including each ScanP popped from the first list, to thereby continuously change the molecular structure.

Thus, the information processing device performs the scan processing in which one or more constraints (conditions of the inequality) based on the ScanP included in the first List[ScanP] are applied in parallel, for example, on the initial molecular structure, and thereby can output a first trajectory as a result. The information processing device then performs the scan processing in which one or more constraints (conditions of the inequality) based on the ScanP included in the second List[ScanP] are applied in parallel, on the final molecular structure of this trajectory (final structure in this trajectory), and thereby can output a trajectory to which the second constraint is sequentially applied based on the first constraint, as a result. The above scan processing is repeated for the third list, the fourth list, . . . , and thereby can calculate the structural change until the final molecular structure and acquire its trajectory.

According to the scan processing sequentially applying the constraint, it is possible to simulate the structural change in the nucleophilic substitution reaction such as a S_{N}2 reaction in which a nucleophile (for example, a first atom) approaches electrophile (for example, a second atom) and a leaving group (for example, a third atom) separates from the electrophile, and output a trajectory.

The information processing device first accepts and sets a plurality of parameter sets ScanPᵢⱼ (S100). Here, a subscript i indicates an index of the outer List of List[List[ScanP]], and a subscript j indicates an index of the inner List. In other words, ScanPᵢⱼ represents a j+1th parameter set ScanP in an i+1th List[ScanP]. Note that assuming that the maximum value of i is I-1, ScanPᵢⱼ includes I List[ScanP]s from a first List[ScanP] to an 1th List[ScanP], and the sequential scan processing is performed I times in order from the first List[ScanP].

Next, the information processing device sets i=0, and starts the scan processing on the target molecular structure (S102). Specifically, the information processing device pops each parameter set ScanP listed in the first List[ScanP] corresponding to ScanP₀ⱼ, and sets to execute the scan processing in which all of the corresponding constraints are applied, on the initial molecular structure based on all of the popped ScanPs.

The information processing device changes the target molecular structure by performing the scan processing according to the setting (S104).

The information processing device repeats the processing at S104 until i reaches I. Specifically, the information processing device determines whether i>=I after the processing at S104 is completed (S106). In the case of NO (S106: NO), the information processing device increments i and performs setting for the next scan processing (S108). More specifically, the information processing device pops each parameter set ScanP listed in the i+1th List [ScanP] corresponding to Scanᵢⱼ. Then, the information processing device sets to perform the scan processing in which all of the corresponding constraints are applied, on the last molecular structure of the trajectory obtained by the immediately preceding scan processing at S104 (the final structure in this trajectory), based on all of the popped ScanPs including each ScanP popped from the first to the ith Lest[ScanP]s.

With this setting, the scan processing continuing from the last scan processing can be sequentially performed at subsequent S104 with the constraint on the user coordinate changed.

When i>=I (more simply, i=I), the information processing device determines that the arithmetic operation has been completed under the condition at S106 (S106: YES), and outputs the trajectory of the molecular structure obtained by the sequential scan processing I times so far, and completes the processing (S110).

As explained above, according to embodiments as some examples in this disclosure, it becomes possible to calculate the structural change according to the force calculated based on the condition of the inequality representing the constraint on the coordinate in an arbitrary user definition. As a result, it becomes possible to realize the scan processing under the condition of not a strong constraint such as until a certain evaluation value reaches a predetermined value but, for example, a constraint in a form of setting a certain coordinate to a certain value or more.

Therefore, it is possible to reduce the amount of information which the user should know in advance in order to change the molecular structure. The user can roughly give the end condition of one structural change by an inequality expression, and therefore the user can give a condition of a serial (sequential) structural change, in which one structural change is followed by another structural change, by a plurality of inequality expressions to facilitate serial (sequential) and automatic search for the change in the molecular structure.

The trained models of above embodiments may be, for example, a concept that includes a model that has been trained as described and then distilled by a general method.

Some or all of each device (at least one of the first information processing device 10 or the second information processing device 20) in the above embodiment may be configured in hardware, or information processing of software (program) executed by, for example, a CPU (Central Processing Unit), GPU (Graphics Processing Unit). In the case of the information processing of software, software that enables at least some of the functions of each device in the above embodiments may be stored in a non-volatile storage medium (non-volatile computer readable medium) such as CD-ROM (Compact Disc Read Only Memory) or USB (Universal Serial Bus) memory, and the information processing of software may be executed by loading the software into a computer. In addition, the software may also be downloaded through a communication network.

Further, entire or a part of the software may be implemented in a circuit such as an ASIC (Application Specific Integrated Circuit) or FPGA (Field Programmable Gate Array), wherein the information processing of the software may be executed by hardware.

A storage medium to store the software may be a removable storage media such as an optical disk, or a fixed type storage medium such as a hard disk, or a memory. The storage medium may be provided inside the computer (a main storage device or an auxiliary storage device) or outside the computer.

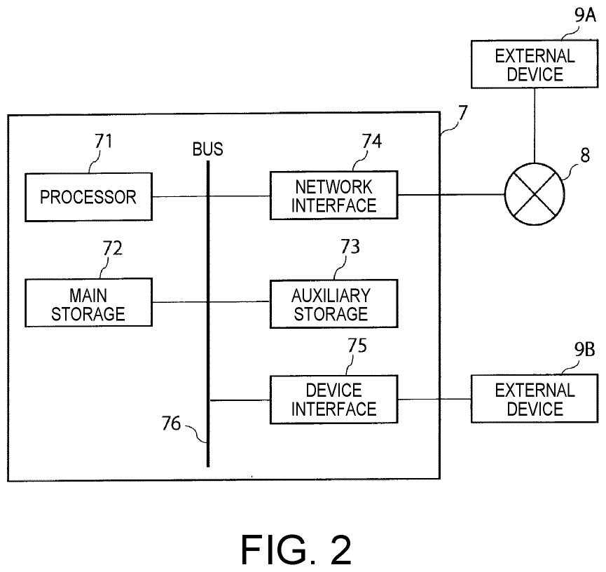

FIG. 2 is a block diagram illustrating an example of a hardware configuration of each device (at least one of the first information processing device 10 or the second information processing device 20) in the above embodiments. As an example, each device may be implemented as a computer 7 provided with a processor 71, a main storage device 72, an auxiliary storage device 73, a network interface 74, and a device interface 75, which are connected via a bus 76.

The computer 7 of FIG. 2 is provided with each component one by one but may be provided with a plurality of the same components. Although one computer 7 is illustrated in FIG. 2, the software may be installed on a plurality of computers, and each of the plurality of computer may execute the same or a different part of the software processing. In this case, it may be in a form of distributed computing where each of the computers communicates with each of the computers through, for example, the network interface 74 to execute the processing. That is, each device (one of the information processing devices) in the above embodiments may be configured as a system where one or more computers execute the instructions stored in one or more storages to enable functions. Each device may be configured such that the information transmitted from a terminal is processed by one or more computers provided on a cloud and results of the processing are transmitted to the terminal.

Various arithmetic operations of each device (one of the information processing devices) in the above embodiments may be executed in parallel processing using one or more processors or using a plurality of computers over a network. The various arithmetic operations may be allocated to a plurality of arithmetic cores in the processor and executed in parallel processing. Some or all the processes, means, or the like of the present disclosure may be implemented by at least one of the processors or the storage devices provided on a cloud that can communicate with the computer 7 via a network. Thus, each device in the above embodiments may be in a form of parallel computing by one or more computers.

The processor 71 may be an electronic circuit (such as, for example, a processor, processing circuitry, processing circuitry, CPU, GPU, FPGA, or ASIC) that executes at least controlling the computer or arithmetic calculations. The processor 71 may also be, for example, a general-purpose processing circuit, a dedicated processing circuit designed to perform specific operations, or a semiconductor device which includes both the general-purpose processing circuit and the dedicated processing circuit. Further, the processor 71 may also include, for example, an optical circuit or an arithmetic function based on quantum computing.

The processor 71 may execute an arithmetic processing based on data and/or a software input from, for example, each device of the internal configuration of the computer 7, and may output an arithmetic result and a control signal, for example, to each device. The processor 71 may control each component of the computer 7 by executing, for example, an OS (Operating System), or an application of the computer 7.

Each device (one of the information processing devices) in the above embodiments may be enabled by one or more processors 71. The processor 71 may refer to one or more electronic circuits located on one chip, or one or more electronic circuitries arranged on two or more chips or devices. In the case of a plurality of electronic circuitries are used, each electronic circuit may communicate by wired or wireless.

The main storage device 72 may store, for example, instructions to be executed by the processor 71 or various data, and the information stored in the main storage device 72 may be read out by the processor 71. The auxiliary storage device 73 is a storage device other than the main storage device 72. These storage devices shall mean any electronic component capable of storing electronic information and may be a semiconductor memory. The semiconductor memory may be either a volatile or non-volatile memory. The storage device for storing various data or the like in each device (one of the information processing devices) in the above embodiments may be enabled by the main storage device 72 or the auxiliary storage device 73 or may be implemented by a built-in memory built into the processor 71. For example, the storages 102 in the above embodiments may be implemented in the main storage device 72 or the auxiliary storage device 73.

In the case of each device (one of the information processing devices) in the above embodiments is configured by at least one storage device (memory) and at least one of a plurality of processors connected/coupled to/with this at least one storage device, at least one of the plurality of processors may be connected to a single storage device. Or at least one of the plurality of storages may be connected to a single processor. Or each device may include a configuration where at least one of the plurality of processors is connected to at least one of the plurality of storage devices. Further, this configuration may be implemented by a storage device and a processor included in a plurality of computers. Moreover, each device may include a configuration where a storage device is integrated with a processor (for example, a cache memory including an L1 cache or an L2 cache).

The network interface 74 is an interface for connecting to a communication network 8 by wireless or wired. The network interface 74 may be an appropriate interface such as an interface compatible with existing communication standards. With the network interface 74, information may be exchanged with an external device 9A connected via the communication network 8. Note that the communication network 8 may be, for example, configured as WAN (Wide Area Network), LAN (Local Area Network), or PAN (Personal Area Network), or a combination of thereof, and may be such that information can be exchanged between the computer 7 and the external device 9A. The internet is an example of WAN, IEEE802.11 or Ethernet (registered trademark) is an example of LAN, and Bluetooth (registered trademark) or NFC (Near Field Communication) is an example of PAN.

The device interface 75 is an interface such as, for example, a USB that directly connects to the external device 9B.

The external device 9A is a device connected to the computer 7 via a network. The external device 9B is a device directly connected to the computer 7.

The external device 9A or the external device 9B may be, as an example, an input device. The input device is, for example, a device such as a camera, a microphone, a motion capture, at least one of various sensors, a keyboard, a mouse, or a touch panel, and gives the acquired information to the computer 7. Further, it may be a device including an input unit such as a personal computer, a tablet terminal, or a smartphone, which may have an input unit, a memory, and a processor.

The external device 9A or the external device 9B may be, as an example, an output device. The output device may be, for example, a display device such as, for example, an LCD (Liquid Crystal Display), or an organic EL (Electro Luminescence) panel, or a speaker which outputs audio. Moreover, it may be a device including an output unit such as, for example, a personal computer, a tablet terminal, or a smartphone, which may have an output unit, a memory, and a processor.

Further, the external device 9A or the external device 9B may be a storage device (memory). The external device 9A may be, for example, a network storage device, and the external device 9B may be, for example, an HDD storage.

Furthermore, the external device 9A or the external device 9B may be a device that has at least one function of the configuration element of each device (one of the information processing devices) in the above embodiments. That is, the computer 7 may transmit a part of or all of processing results to the external device 9A or the external device 9B, or receive a part of or all of processing results from the external device 9A or the external device 9B.

In the present specification (including the claims), the representation (including similar expressions) of “at least one of a, b, and c” or “at least one of a, b, or c” includes any combinations of a, b, c, a-b, a-c, b-c, and a-b-c. It also covers combinations with multiple instances of any element such as, for example, a-a, a-b-b, or a-a-b-b-c-c. It further covers, for example, adding another element d beyond a, b, and/or c, such that a-b-c-d.

In the present specification (including the claims), the expressions such as, for example, “data as input,” “using data,” “based on data,” “according to data,” or “in accordance with data” (including similar expressions) are used, unless otherwise specified, this includes cases where data itself is used, or the cases where data is processed in some ways (for example, noise added data, normalized data, feature quantities extracted from the data, or intermediate representation of the data) are used. When it is stated that some results can be obtained “by inputting data,” “by using data,” “based on data,” “according to data,” “in accordance with data” (including similar expressions), unless otherwise specified, this may include cases where the result is obtained based only on the data, and may also include cases where the result is obtained by being affected factors, conditions, and/or states, or the like by other data than the data. When it is stated that “output/outputting data” (including similar expressions), unless otherwise specified, this also includes cases where the data itself is used as output, or the cases where the data is processed in some ways (for example, the data added noise, the data normalized, feature quantity extracted from the data, or intermediate representation of the data) is used as the output.

In the present specification (including the claims), when the terms such as “connected (connection)” and “coupled (coupling)” are used, they are intended as non-limiting terms that include any of “direct connection/coupling,” “indirect connection/coupling,” “electrically connection/coupling,” “communicatively connection/coupling,” “operatively connection/coupling,” “physically connection/coupling,” or the like. The terms should be interpreted accordingly, depending on the context in which they are used, but any forms of connection/coupling that are not intentionally or naturally excluded should be construed as included in the terms and interpreted in a non-exclusive manner.

In the present specification (including the claims), when the expression such as “A configured to B,” this may include that a physically structure of A has a configuration that can execute operation B, as well as a permanent or a temporary setting/configuration of element A is configured/set to actually execute operation B. For example, when the element A is a general-purpose processor, the processor may have a hardware configuration capable of executing the operation B and may be configured to actually execute the operation B by setting the permanent or the temporary program (instructions). Moreover, when the element A is a dedicated processor, a dedicated arithmetic circuit, or the like, a circuit structure of the processor or the like may be implemented to actually execute the operation B, irrespective of whether or not control instructions and data are actually attached thereto.

In the present specification (including the claims), when a term referring to inclusion or possession (for example, “comprising/including,” “having,” or the like) is used, it is intended as an open-ended term, including the case of inclusion or possession an object other than the object indicated by the object of the term. If the object of these terms implying inclusion or possession is an expression that does not specify a quantity or suggests a singular number (an expression with a or an article), the expression should be construed as not being limited to a specific number.

In the present specification (including the claims), although when the expression such as “one or more,” “at least one,” or the like is used in some places, and the expression that does not specify a quantity or suggests a singular number (the expression with a or an article) is used elsewhere, it is not intended that this expression means “one.” In general, the expression that does not specify a quantity or suggests a singular number (the expression with a or an as article) should be interpreted as not necessarily limited to a specific number.

In the present specification, when it is stated that a particular configuration of an example results in a particular effect (advantage/result), unless there are some other reasons, it should be understood that the effect is also obtained for one or more other embodiments having the configuration. However, it should be understood that the presence or absence of such an effect generally depends on various factors, conditions, and/or states, etc., and that such an effect is not always achieved by the configuration. The effect is merely achieved by the configuration in the embodiments when various factors, conditions, and/or states, etc., are met, but the effect is not always obtained in the claimed invention that defines the configuration or a similar configuration.

In the present specification (including the claims), when the term such as “maximize/maximization” is used, this includes finding a global maximum value, finding an approximate value of the global maximum value, finding a local maximum value, and finding an approximate value of the local maximum value, should be interpreted as appropriate accordingly depending on the context in which the term is used. It also includes finding on the approximated value of these maximum values probabilistically or heuristically. Similarly, when the term such as “minimize/minimization” is used, this includes finding a global minimum value, finding an approximated value of the global minimum value, finding a local minimum value, and finding an approximated value of the local minimum value, and should be interpreted as appropriate accordingly depending on the context in which the term is used. It also includes finding the approximated value of these minimum values probabilistically or heuristically. Similarly, when the term such as “optimize/optimization” is used, this includes finding a global optimum value, finding an approximated value of the global optimum value, finding a local optimum value, and finding an approximated value of the local optimum value, and should be interpreted as appropriate accordingly depending on the context in which the term is used. It also includes finding the approximated value of these optimal values probabilistically or heuristically.

In the present specification (including claims), when a plurality of hardware performs a predetermined process, the respective hardware may cooperate to perform the predetermined process, or some hardware may perform all the predetermined process. Further, a part of the hardware may perform a part of the predetermined process, and the other hardware may perform the rest of the predetermined process. In the present specification (including claims), when an expression (including similar expressions) such as “one or more hardware perform a first process and the one or more hardware perform a second process,” or the like, is used, the hardware that perform the first process and the hardware that perform the second process may be the same hardware, or may be the different hardware. That is: the hardware that perform the first process and the hardware that perform the second process may be included in the one or more hardware. Note that, the hardware may include an electronic circuit, a device including the electronic circuit, or the like.

In the present specification (including the claims), when a plurality of storage devices (memories) store data, an individual storage device among the plurality of storage devices may store only a part of the data or may store the entire data. Further, some storage devices among the plurality of storage devices may include a configuration for storing data.

While certain embodiments of the present disclosure have been described in detail above, the present disclosure is not limited to the individual embodiments described above. Various additions, changes, substitutions, partial deletions, etc. are possible to the extent that they do not deviate from the conceptual idea and purpose of the present disclosure derived from the contents specified in the claims and their equivalents. For example, when numerical values or mathematical formulas are used in the description in the above-described embodiments, they are shown for illustrative purposes only and do not limit the scope of the present disclosure. Further, the order of each operation shown in the embodiments is also an example, and does not limit the scope of the present disclosure.

1. An information processing device, comprising:
one or more memories; and
one or more processors configured to:
set a first structure of a plurality of atoms; and
repeatedly calculate a structural change of the plurality of atoms from the first structure to a second structure of the plurality of atoms under a condition to be satisfied by at least the second structure with regard to an atomic structure to focus on, the condition including an inequality, to search for a trajectory of a structure of the plurality of atoms from the first structure to the second structure.

2. The information processing device according to claim 1, wherein the inequality is formed by a magnitude relation between an index of a positional relationship of the atomic structure to focus on and an objective value.

3. The information processing device according to claim 1, wherein the one or more processors are configured to:
search for the trajectory by repeatedly calculating force to be applied on at least one of the plurality of atoms and repeatedly calculating the structural change of the plurality of atoms based on the force, under the condition including the inequality; and
calculate the force using a function whose shape is set based on the inequality.

4. The information processing device according to claim 3, wherein the function whose shape is set based on the inequality is a function for which an equation for calculating a value of the force is switched based on the inequality.

5. The information processing device according to claim 3, wherein the repeated calculation of the structural change is a calculation of numerically solving a differential equation based on the repeatedly calculated force.

6. The information processing device according to claim 3, wherein the repeated calculation of the structural change is an optimization calculation of the structure of the plurality of atoms based on the repeatedly calculated force.

7. The information processing device according to claim 1, wherein the one or more processors are configured to set the condition to be satisfied, by a plurality of conditions including an inequality.

8. The information processing device according to claim 7, wherein the one or more processors are configured to repeatedly calculate the structural change with the plurality of conditions including the inequality applied in parallel.

9. The information processing device according to claim 7, wherein the one or more processors are configured to repeatedly calculate the structural change with the plurality of conditions including the inequality applied sequentially.

10. The information processing device according to claim 1, wherein the condition including the inequality is described by an inequality about a function definable by a user.

11. The information processing device according to claim 10, wherein the function is defined based on at least a bond distance between atoms.

12. The information processing device according to claim 10, wherein the function is defined using at least information on three or more atoms as an input.

13. The information processing device according to claim 12, wherein
the function is defined based on at least a bond angle formed by three atoms or a dihedral angle.

14. The information processing device according to claim 1, wherein the first structure and the second structure are an initial structure of the plurality of atoms in a chemical reaction and a final structure of the plurality of atoms in the chemical reaction, respectively.

15. The information processing device according to claim 1, wherein the repeated calculation of the structural change includes repeatedly calculating the structural change of the plurality of atoms under the condition including the inequality and an additional condition including another inequality after repeatedly calculating the structural change of the plurality of atoms under the condition without the additional condition.

16. The information processing device according to claim 1, wherein the repeated calculation of the structural change includes repeatedly calculating the structural change of the plurality of the atoms under the condition including inequality and another condition including inequality.

17. The information processing device according to claim 1, wherein the condition including the inequality and the atomic structure to focus on are defined by a user.

18. The information processing device according to claim 17, wherein the condition including the inequality forms a constraint to make a positional relationship of the atomic structure to focus on fall within a predetermined range given by the user.

19. An information processing method, comprising
setting, by one or more processors, a first structure of a plurality of atoms; and
repeatedly calculating, by the one or more processors, a structural change of the plurality of atoms from the first structure to a second structure of the plurality of atoms under a condition to be satisfied by at least the second structure with regard to an atomic structure to focus on, the condition including an inequality, to search for a trajectory of a structure of the plurality of atoms from the first structure to the second structure.

20. A non-transitory computer readable medium storing a program causing one or more processors to execute an information processing method, the information processing method comprising
setting a first structure of a plurality of atoms; and
repeatedly calculating a structural change of the plurality of atoms from the first structure to a second structure of the plurality of atoms under a condition to be satisfied by at least the second structure with regard to an atomic structure to focus on, the condition including an inequality, to search for a trajectory of a structure of the plurality of atoms from the first structure to the second structure.
